(19) United States
(12) Patent Application Publication
(10) Pub. No.: US 2026/0342316 A1
(43) Pub. Date: Oct. 29, 2026

(54) RAYLEIGH MODE LOW-LOSS RESONATOR TECHNOLOGY SURFACE ACOUSTIC WAVE (RM-LRT-SAW) DEVICES AND APPLICATIONS THEREOF

(71) Applicant: Qorvo US, Inc., Greensboro, NC (US)

(72) Inventor: Patrik Rath, Schwaebisch Gmuend (DE)

(21) Appl. No.: 19/549,824

(22) Filed: Feb. 25, 2026

Related U.S. Application Data
(60) Provisional application No. 63/796,190, filed on Apr. 28, 2025.

(51) Int. Cl. H03H 9/64; H03H 3/08; H03H 9/25

(52) U.S. Cl. CPC H03H 9/6489; H03H 3/08; H03H 9/25

(57) ABSTRACT

A surface acoustic wave (SAW) resonator and a filter comprising the same are provided. The SAW resonator and filter may include at least one dielectric layer disposed on a substrate, at least one piezoelectric layer disposed on the dielectric layer, and an interdigital transducer (IDT) disposed on the piezoelectric layer. The IDT is configured to generate Rayleigh waves and shear waves in the piezoelectric layer. The SAW resonator and filter may be configured to operate in a frequency range between about 500 MHz and about 1.5 GHz in a Rayleigh mode as a main mode with a shear mode as a spurious mode that is suppressed. The piezoelectric layer may include lithium tantalate or lithium niobate. The dielectric layer may include silicon oxide, aluminum oxide, silicon nitride, or silicon oxynitride. The substrate may include silicon, sapphire, quartz, silicon carbide, or diamond.

### CROSS-REFERENCE TO RELATED APPLICATION

This application claims priority to U.S. Patent Application No. 63/796,190, filed Apr. 28, 2025, all of which is incorporated by reference herein in its entirety.

### TECHNICAL FIELD

The present disclosure relates generally to surface acoustic wave (SAW) devices, and in particular, relates to low-loss resonator technology SAW (LRT-SAW) devices that offer good device performance with minimal spurious modes.

### BACKGROUND

Acoustic wave resonators are devices that use a piezoelectric material to convert two types of energies into one another. A typical acoustic wave resonator device converts electrical signals into mechanical vibrations, or vice versa, by converting electrical energy into mechanical energy, or vice versa. Using this principle, the acoustic wave resonator device can send, filter, or otherwise process the electrical and mechanical signals back and forth, and thus, are commonly used in electronic communication devices. Due to their small component sizes, low costs in manufacturing, and highly reliability, these resonator devices are widely used as electronic filters in compact electronic devices.

Some of the more commonly used electronic filters use bulk acoustic wave (BAW) and surface acoustic wave (SAW) resonators. Among these technologies, low-loss resonator technology surface acoustic wave (LRT-SAW) devices achieve some of the highest performances. In LRT-SAWs, which can be referred to as thin film SAW or guided SAW, the Shear mode is the main mode, and the Rayleigh mode is considered spurious and thus typically suppressed. In order to achieve performance superiority, the LRT-SAW technology utilizes bonded wafers where a shear wave in the acoustic waves is mainly localized within a thin piezoelectric film. With this approach LRT-SAW resonators can achieve resonator coupling, k2e, of about 11%, with a large quality “Q” factor and a good temperature coefficient of frequency (TCF).

However, an important challenge for LRT-SAW based technology is to significantly reduce the size of resonators and filters, while maintaining good performance. A well-known approach for size reduction is to use thicker or denser interdigital transducer (IDT) metal stacks to reduce the acoustic velocity, and hence, size. This typically comes at the expense of reduction in the Q factor, associated with damping in the metal. Additionally, the major spurious mode (e.g., the Rayleigh mode) for LRT-SAWs resides in frequency below the main mode (e.g., the Shear mode). This spurious mode and its transverse modes can impact the performance of filters and multiplexers, when dimensions of the LRT-SAW resonators are reduced. Thus, a solution is needed to combine or maintain great performance while dimensions of the LRT-SAW devices are reduced, while simultaneously ensuring the LRT-SAW based filters and multiplexers are not impacted by the undesired spurious modes.

### SUMMARY

Embodiments of the present disclosure include low-loss resonator technology surface acoustic wave (LRT-SAW) devices having reduced features that offer good device performance with minimal spurious modes. Aspects of the disclosure advantageously provide LRT-SAW devices with good device performance with minimal spurious modes for use in wireless devices and wireless communications systems.

In an exemplary aspect, a surface acoustic wave resonator is provided. The surface acoustic wave resonator includes at least one dielectric layer disposed on a substrate; at least one piezoelectric layer disposed on the at least one dielectric layer; and an interdigital transducer (IDT) disposed on the at least one piezoelectric layer, wherein the IDT is configured to generate Rayleigh waves and shear waves in the piezoelectric layer.

In one or more embodiments of the surface acoustic wave resonator, the at least one piezoelectric layer includes a lithium niobate having a crystal cut angle between 110 degrees and 130 degrees YX. In one or more embodiments, the at least one piezoelectric layer comprises a lithium niobate having a crystal cut angle between 115 degrees and 125 degrees YX. In one or more embodiments, the at least one piezoelectric layer includes lithium niobate having a crystal cut angle of 120 degrees YX.

In one or more embodiments, the at least one piezoelectric layer has a thickness between about 0.1 µm and about 10 µm. In one or more embodiments, the at least one piezoelectric layer has a thickness between about 0.3 µm and about 1.5 µm. In one or more embodiments, the at least one dielectric layer comprises silicon oxide and has a thickness between about 0.1 µm and about 5 µm. In one or more embodiments, the at least one dielectric layer comprises silicon oxide and has a thickness between about 0.5 µm and about 3 µm.

In one or more embodiments, the at least one piezoelectric layer includes lithium tantalate, lithium niobate, or a combination thereof. In one or more embodiments, the at least one dielectric layer includes silicon oxide, aluminum oxide, silicon nitride, silicon oxynitride, or any suitable dielectric material. In one or more embodiments, the substrate includes silicon, sapphire, quartz, silicon carbide, diamond, or a combination thereof.

In one or more embodiments, the shear waves vibrate at a frequency that is about 50 MHz to about 600 MHz larger than an anti-resonant frequency of the generated Rayleigh waves. In one or more embodiments, a difference between an anti-resonant frequency of the generated Rayleigh waves and a resonant frequency of the shear waves is larger than a frequency difference between a resonant frequency and an anti-resonant frequency of the generated Rayleigh waves. In one or more embodiments, the surface acoustic wave resonator may be configured to operate in a Rayleigh mode as a main mode with a shear mode as a spurious mode that is suppressed, wherein the spurious mode has a higher frequency than the main mode; operate in a frequency range between about 500 MHz and about 1.5 GHz or between about 1.5 GHz and about 3.0 GHz; or a combination thereof.

In an exemplary aspect, a filter is provided. The filter includes at least one surface acoustic wave resonator that includes at least one dielectric layer disposed on a substrate; at least one piezoelectric layer disposed on the at least one dielectric layer; and an interdigital transducer (IDT) disposed on the at least one piezoelectric layer, wherein the IDT is configured to generate Rayleigh waves and shear waves in the piezoelectric layer.

In one or more embodiments of the filter, the at least one piezoelectric layer comprises lithium niobate having a crystal cut angle between 110 degrees and 130 degrees YX. In one or more embodiments, the at least one piezoelectric layer includes a lithium niobate having a crystal cut angle between 115 degrees and 125 degrees YX. In one or more embodiments, the at least one piezoelectric layer includes lithium niobate having a crystal cut angle of 120 degrees YX. In one or more embodiments, the at least one piezoelectric layer has a thickness between about 0.1 µm and about 10 µm. In one or more embodiments, the at least one piezoelectric layer has a thickness between about 0.3 µm and about 1.5 µm. In one or more embodiments, the at least one dielectric layer comprises silicon oxide and has a thickness between about 0.1 µm and about 5 µm. In one or more embodiments, the at least one dielectric layer comprises silicon oxide and has a thickness between about 0.5 µm and about 3 µm.

In one or more embodiments, the at least one piezoelectric layer includes lithium tantalate, lithium niobate, or a combination thereof. In one or more embodiments, the at least one dielectric layer includes silicon oxide, aluminum oxide, silicon nitride, silicon oxynitride, or any suitable dielectric material. In one or more embodiments, the substrate includes silicon, sapphire, quartz, silicon carbide, diamond, or a combination thereof.

In one or more embodiments, the shear waves vibrate at a frequency that is about 50 MHz to about 600 MHz larger than an anti-resonant frequency of the generated Rayleigh waves. In one or more embodiments, a difference between an anti-resonant frequency of the generated Rayleigh waves and a resonant frequency of the shear waves is larger than a frequency difference between a resonant frequency and an anti-resonant frequency of the generated Rayleigh waves.

In one or more embodiments, the at least one surface acoustic wave resonator is configured to operate in a Rayleigh mode as a main mode with a shear mode as a spurious mode that is suppressed, wherein the spurious mode has a higher frequency than the main mode; operate in a frequency range between about 500 MHz and about 1.5 GHz or between about 1.5 GHz and about 3.0 GHz; or a combination thereof.

In an exemplary aspect, a method for preparing a surface acoustic wave device is provided. The method includes disposing at least one piezoelectric layer atop a substrate having at least one dielectric layer; and disposing an interdigital transducer (IDT) on the at least one piezoelectric layer, wherein the IDT is configured to generate Rayleigh waves and shear waves in the piezoelectric layer. In one or more embodiments, the IDT comprises suitable materials, to ensure good electrical conductivity, high reflectivity for the excited waves, as well as good stability under power and increased temperatures.

In one or more embodiments of the method, the at least one piezoelectric layer includes lithium niobate having a crystal cut angle between 115 degrees and 125 degrees YX, has a thickness between about 0.1 µm and about 10 µm, or a combination thereof. In one or more embodiments, the at least one piezoelectric layer has a thickness between about 0.3 µm and about 1.5 µm. In one or more embodiments, the at least one dielectric layer comprises silicon oxide and has a thickness between about 0.1 µm and about 5 µm. In one or more embodiments, the at least one dielectric layer comprises silicon oxide and has a thickness between about 0.5 µm and about 3 µm. In one or more embodiments, the at least one piezoelectric layer includes lithium niobate having a crystal cut angle of 120 degrees YX.

In one or more embodiments, at least one piezoelectric layer includes lithium tantalate, lithium niobate, or a combination thereof. In one or more embodiments, the at least one dielectric layer includes silicon oxide, aluminum oxide, silicon nitride, silicon oxynitride, or any suitable dielectric material. In one or more embodiments, the substrate includes silicon, sapphire, quartz, silicon carbide, diamond, or a combination thereof.

In one or more embodiments, the shear waves vibrate at a frequency that is about 50 MHz to about 600 MHz larger than an anti-resonant frequency of the generated Rayleigh waves. In one or more embodiments, a difference between an anti-resonant frequency of the generated Rayleigh waves and a resonant frequency of the shear waves is larger than a frequency difference between a resonant frequency and an anti-resonant frequency of the generated Rayleigh waves. In one or more embodiments, the surface acoustic wave device is configured to operate in a Rayleigh mode as a main mode with a shear mode as a spurious mode that is suppressed, wherein the spurious mode has a higher frequency than the main mode. In one or more embodiments, the surface acoustic wave device is configured to operate in a frequency range between about 500 MHz and about 1.5 GHz.

Additional aspects, features, and advantages of the present disclosure will become apparent from the following detailed description.

### BRIEF DESCRIPTION OF THE DRAWINGS

Illustrative embodiments of the present disclosure will be described with reference to the accompanying drawings, of which:

FIG. 1 illustrates a perspective view of a representative surface acoustic wave (SAW) device, according to aspects of the present disclosure.

FIG. 2A illustrates a cross-sectional view of an example Rayleigh mode low-loss resonator technology surface acoustic wave (RM-LRT-SAW) device, according to aspects of the present disclosure.

FIG. 2B shows a finite element simulation of a Rayleigh mode of the RM-LRT-SAW device of FIG. 2A, according to aspects of the present disclosure.

FIG. 2C shows a finite element simulation of a Shear mode of the RM-LRT-SAW device of FIG. 2A, according to aspects of the present disclosure.

FIGS. 3A and 3B depict graphical representations of a resonator response for an example RM-LRT-SAW device, according to aspects of the present disclosure.

FIGS. 4A and 4B depict graphical representations of how a resonator response changes with changes in the thickness of the piezoelectric layer of an example RM-LRT-SAW device, according to aspects of the present disclosure.

FIGS. 5A and 5B depict graphical representations of a resonator response for an example RM-LRT-SAW device, according to aspects of the present disclosure.

FIG. 6 illustrates a flowchart for a method for preparing a surface acoustic wave device, according to aspects of the present disclosure.

FIG. 7 illustrates an electronic device or a wireless device comprising a surface acoustic wave device, according to aspects of the present disclosure.

### DETAILED DESCRIPTION

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

Embodiments of the present disclosure include surface acoustic wave resonators and filters based on low-loss resonator technology surface acoustic wave (LRT-SAW) devices. These devices offer smaller component features with offer great performances based on novel well isolated main modes with heavily suppressed spurious modes. Specifically, the disclosed devices enable using Rayleigh mode as the main mode and the shear mode as spurious mode. The disclosed Rayleigh mode LRT-SAW (RM-LRT-SAW) device may be utilized as a resonator or as part of a filter, including for example, ladder filters, coupled resonator filters (CRF), or any other suitable filters. Moreover, the RM-LRT-SAW devices can be configured to perform in low frequency bands (e.g., between about 500 MHz and about 1.5 GHz), as well as in higher frequency bands (e.g., higher than about 1.5 GHz). Accordingly, the disclosed RM-LRT-SAW-based resonators and filters are suitable for use in electronic and communication systems and devices, such as for example, but not limited to, global position system (GPS), satellites, wireless systems, for example, as base stations or WiFi filters, or any suitable mobile communications and applications, etc.

In one or more embodiments, the disclosed resonators and filters are configured to achieve performance characteristics, including, for example, having a large flexible range of coupling values and a high performance in frequency bands between, e.g., about 500 MHz and about 1.5 GHz. With a good heat dissipation with low temperature under power, the disclosed RM-LRT-SAW technology may provide the ability to form SAW devices with large velocity differences between the available Shear mode (spurious mode) and Rayleigh mode (main mode), with thick and/or dense IDT metal stacks with reduced size dimensions, while offering a clean out-of-band response, which may be suitable for ripple-free filters and multiplexers that simultaneously offer large capacitance / area values and high coupling values of k2e at increased duty factor required for reduced size dimensions.

In accordance with one or more embodiments herein, a surface acoustic wave resonator based on the disclosed RM-LRT-SAW technology is provided. In one or more embodiments, a filter that includes at least one RM-LRT-SAW resonator is provided. In one or more embodiments, the RM-LRT-SAW resonator may include at least one dielectric layer disposed on a substrate, at least one piezoelectric layer disposed on the at least one dielectric layer, and an interdigital transducer (IDT) disposed on the at least one piezoelectric layer, wherein the IDT is configured to generate Rayleigh waves and shear waves in the piezoelectric layer.

In one or more embodiments, a method for preparing a RM-LRT-SAW device is provided. The method may include disposing at least one piezoelectric layer atop a substrate having at least one dielectric layer; and disposing an IDT on the at least one piezoelectric layer. In one or more embodiments, the piezoelectric layer may include a lithium niobate having a crystal cut angle between 115 degrees and 125 degrees YX. In one or more embodiments, the piezoelectric layer may include lithium niobate having a crystal cut angle of 120 degrees YX. In one or more embodiments, the piezoelectric layer may have a thickness between about 0.1 µm and about 10 µm. In one or more embodiments, the piezoelectric layer may include lithium tantalate, lithium niobate, or a combination thereof. In one or more embodiments, the dielectric layer may include silicon oxide, aluminum oxide, silicon nitride, silicon oxynitride, or any suitable dielectric material. In one or more embodiments, the substrate may include silicon, sapphire, quartz, silicon carbide, diamond, or a combination thereof. In one or more embodiments, the shear waves may vibrate at a frequency that is about 50 MHz to about 600 MHz larger than an anti-resonant frequency of the generated Rayleigh waves. In one or more embodiments, a difference between an anti-resonant frequency of the generated Rayleigh waves and a resonant frequency of the shear waves is larger than a frequency difference between a resonant frequency and an anti-resonant frequency of the generated Rayleigh waves. In one or more embodiments, the disclosed RM-LRT-SAW resonator may be configured to operate in a Rayleigh mode as a main mode with a shear mode as a spurious mode that is suppressed, wherein the spurious mode has a higher frequency than the main mode, operate in a frequency range between about 500 MHz and about 1.5 GHz, or both.

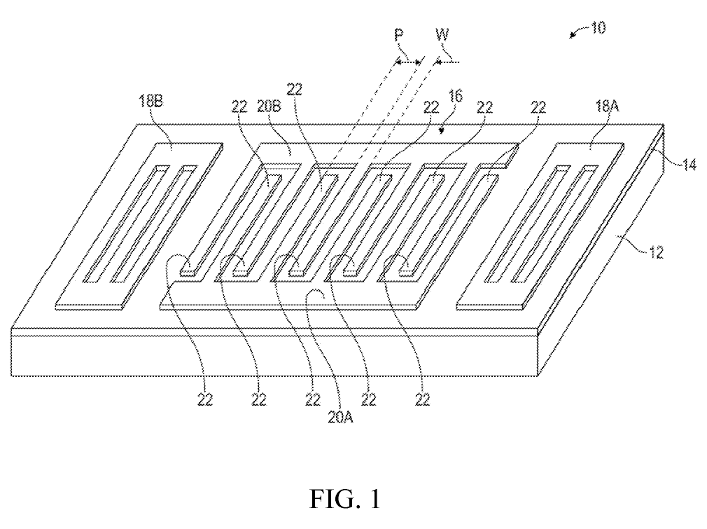

Various embodiments of the disclosed Rayleigh mode low-loss resonator technology surface acoustic wave (RM-LRT-SAW) devices are described below in further detail with respect to the FIGS. 1, 2A, 2B, 2C, 3A, 3B, 4A, 4B, 5A, 5B, 6, and 7.

FIG. 1 illustrates a perspective view of a representative surface acoustic wave (SAW) device 10, according to aspects of the present disclosure. While this disclosure describes principles of the invention in the context of a SAW resonator, it should be understood that the technology presented may be applied to any suitable type of acoustic wave (AW) resonator, including SAW resonators and bulk AW (BAW) resonators equally. It particularly can be applied to any AW resonator that employs interdigital transducer electrodes, for various orientations of the acoustic wave propagation and the displacements with respect to the arrangement of the electrodes.

As illustrated in FIG. 1, the SAW device 10 includes a substrate 12, a piezoelectric layer 14 on the substrate 12, an interdigital transducer (IDT) 16 including electrodes 22 on a surface of the piezoelectric layer 14 opposite the substrate 12, a first reflector structure 18A on the surface of the piezoelectric layer 14 adjacent to the interdigital transducer 16, and a second reflector structure 18B on the surface of the piezoelectric layer 14 adjacent to the interdigital transducer 16 opposite the first reflector structure 18A. In some aspects, an interdigital transducer may also be referred to as an interdigitated transducer. In certain aspects, the substrate 12 may be referred to as a carrier substrate and the overall SAW device 10 may be referred to as a low-loss resonator technology SAW (LRT-SAW) device, a multi-layer SAW device, a thin film SAW device, a guided SAW device, or any other suitable term.

As shown in FIG. 1, the interdigital transducer 16 includes a first electrode 20A and a second electrode 20B, each of which include a number of electrodes 22 that are interleaved with one another as shown. The first electrode 20A and the second electrode 20B may also be referred to as comb electrodes. A lateral distance between adjacent electrodes 22 of the first electrode 20A and the second electrode 20B defines a pitch P between adjacent electrodes 22. The pitch P may at least partially define a resonant frequency of the corresponding electrode(s) 22. In that regard, in embodiments in which the pitch P between electrodes 22 is uniform, all electrodes 22 may be configured to correspond to the same resonant frequency. This resonant frequency may be the resonant frequency of the SAW device 10. A resonant frequency may be the center frequency or primary frequency of mechanical waves generated in the piezoelectric layer 14 by one or more electrodes 22. An electrode width W of the adjacent electrodes 22 together with the pitch P may define a metallization ratio, or duty factor DF=W/P, of electrodes 22.

In operation, an alternating electrical input signal provided at the first electrode 20A is transduced into a mechanical signal in the piezoelectric layer 14, resulting in one or more acoustic waves therein. In the case of the SAW device 10, the resulting acoustic waves are predominately surface acoustic waves. As discussed above, due to the pitch P and the metallization ratio of the interdigital transducer 16, the characteristics of the material of the piezoelectric layer 14, and other factors, the magnitude and frequency of the acoustic waves transduced in the piezoelectric layer 14 are dependent on the frequency of the alternating electrical input signal. This frequency dependence is often described in terms of changes in the impedance and/or a phase shift between the first electrode 20A and the second electrode 20B with respect to the frequency of the alternating electrical input signal. An alternating electrical potential between the two electrodes 20A and 20B creates an electrical field in the piezoelectric material which generates acoustic waves. The acoustic waves travel at the surface and eventually are transferred back into an electrical signal between the electrodes 20A and 20B. The first reflector structure 18A and the second reflector structure 18B reflect the acoustic waves in the piezoelectric layer 14 back towards the interdigital transducer 16 to confine the acoustic waves in the area surrounding the interdigital transducer 16.

In one or more embodiments, the substrate 12 may comprise various materials including glass, sapphire, quartz, diamond, silicon (Si), or gallium arsenide (GaAs) among others, with Si being a common choice. The piezoelectric layer 14 may be formed of any suitable piezoelectric material(s). In certain embodiments described herein, the piezoelectric layer 14 is formed of lithium tantalate (LT), or lithium niobate (LiNbO₃ or LN), but is not limited thereto. In certain embodiments, the piezoelectric layer 14 is thick enough or rigid enough to function as a piezoelectric substrate. In certain embodiments, the piezoelectric layer 14 is thin enough to function as a piezoelectric material that confines the acoustic waves therewithin. Accordingly, the substrate 12 in FIG. 1 may be omitted. Those skilled in the art will appreciate that the principles of the present disclosure may apply to other materials for the substrate 12 and the piezoelectric layer 14.

In one or more embodiments, the interdigital transducer 16, the first reflector structure 18A, and the second reflector structure 18B may comprise one or more electrically conductive materials, including silver (Au), gold (Ag), tungsten (W), molybdenum (Mo), Nickel (Ni), ruthenium (Ru), iridium (Ir), chromium (Cr), platinum (Pt), titanium (Ti), aluminum (Al), copper (Cu) and alloys thereof as well as alloys with other suitable materials and can be made of either single or multiple layer arrangements, among others. While not shown to avoid obscuring the drawings, additional dielectric layers or any other layers may be provided over all or a portion of the exposed surface of the piezoelectric layer 14, the interdigital transducer 16, the first reflector structure 18A, and the second reflector structure 18B. Such additional passivation layers can form any surface topography, including but not limited to conformal coatings and flat surfaces. Such additional dielectric layers may be provided for passivation, for frequency trimming, for temperature compensation purposes and/or improved thermal conductivity, among other reasons. Suitable materials for such layers include silicon oxide, silicon nitride, titanium oxide, aluminum oxide and can also include dopants such as fluorine. Further, one or more layers may be provided between the substrate 12 and the piezoelectric layer 14 in various embodiments.

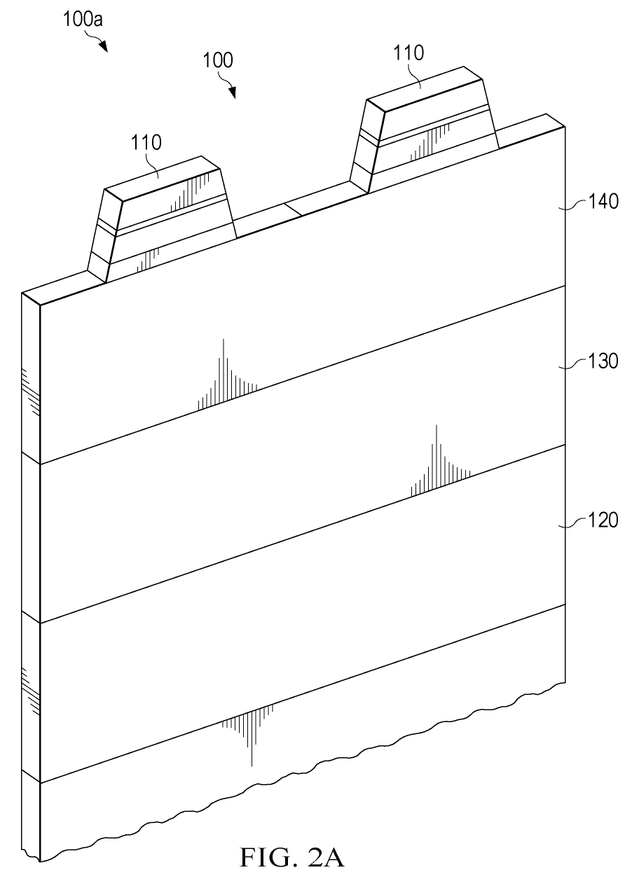

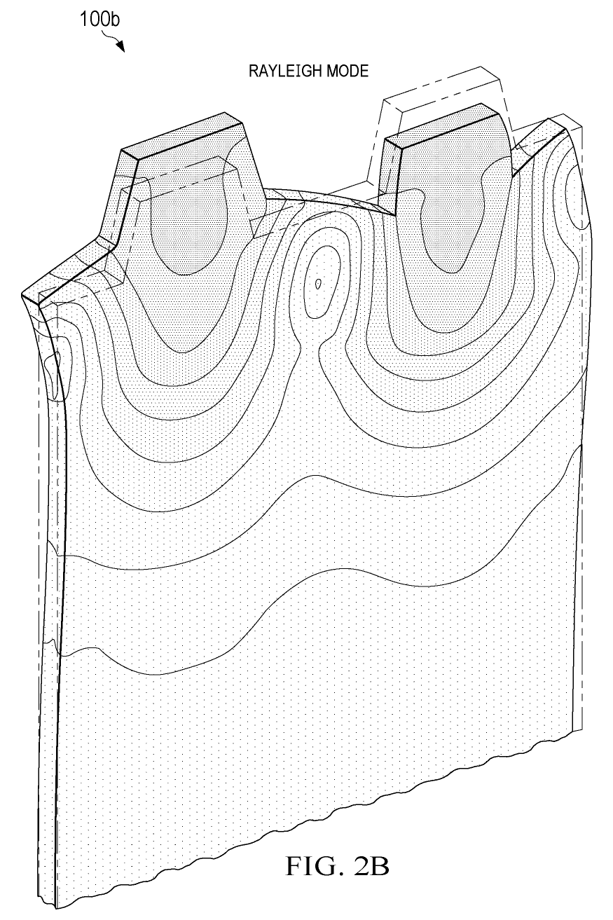

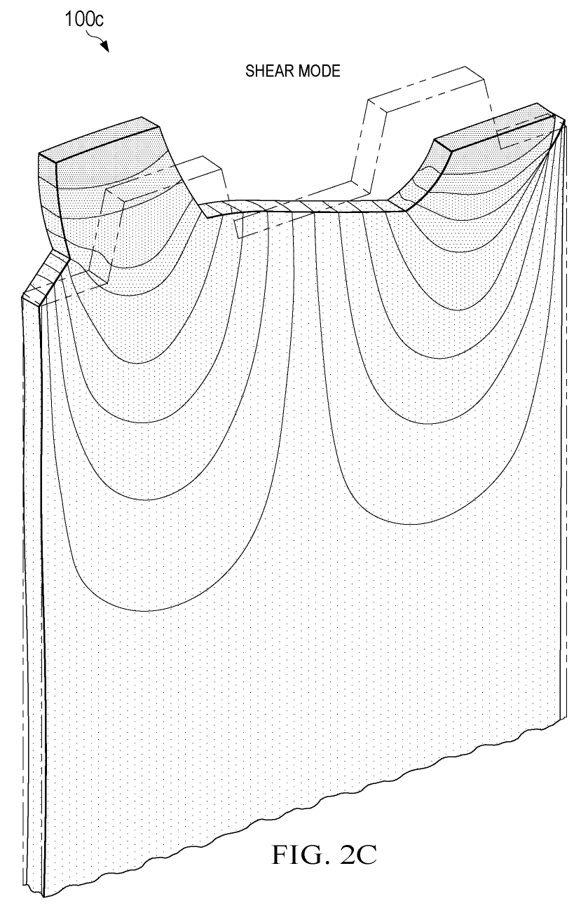

FIG. 2A illustrates a cross-sectional view 100a of an example Rayleigh mode low-loss resonator technology surface acoustic wave (RM-LRT-SAW) device 100, FIG. 2B shows a simulation 100b of a Rayleigh mode of the device 100, and FIG. 2C shows a simulation 100c of a Shear mode of the device 100, according to aspects of the present disclosure. As illustrated in the cross-sectional view 100a of FIG. 2A, the device 100 includes IDTs 110 disposed atop a piezoelectric layer 140, which is disposed on a dielectric layer 130 that is disposed on top of a substrate 120. In various embodiments, the IDTs 110 are identical or similar to the IDT 16, as shown and described with respect to FIG. 1, and thus, will not be described in further detail, unless otherwise noted. In various embodiments, the piezoelectric layer 140 is identical or similar to the piezoelectric layer 14, as shown and described with respect to FIG. 1, and thus, will not be described in further detail, unless otherwise noted. In various embodiments, the dielectric layer 130 may include silicon oxide, such as a buried oxide on a silicon substrate, aluminum oxide, silicon nitride, silicon oxynitride, or any suitable dielectric material. In one or more embodiments, the dielectric layer 130 includes silicon oxide and has a thickness between about 0.1 µm and about 5 µm. In one or more embodiments, the dielectric layer 130 includes silicon oxide and has a thickness between about 0.5 µm and about 3 µm. In various embodiments, the substrate 120 is identical or similar to the substrate 12, as shown and described with respect to FIG. 1, and thus, will not be described in further detail, unless otherwise noted.

In contrast to the disclosed RM-LRT-SAW technology, the standard LRT utilizes a shear mode on lithium tantalate (LT) as the main mode and can achieve great performance, with high Q, low TCF and k2e close to 10%. However, when the device components are reduced to smaller dimensions, achieving a proper wave velocity and capacitance per area of standard LRT resonators can be challenging, particularly for small resonators and small filters. Thus, when dimensions are reduced, the disclosed RM-LRT-SAW technology provides rather improved device performance and characteristics.

FIGS. 2B and 2C respectively show simulations 100b and 100c of the RM-LRT-SAW device 100 of FIG. 2A. Specifically, the simulation 100b shows the main mode, which is a Rayleigh mode and the simulation 100c shows the spurious mode, which is a Shear mode. The piezoelectric material used for the piezoelectric layer 140 may be lithium niobate (LN), and the dielectric layer used in the simulation is buried oxide layer (BOX) on top of silicon substrate. Other materials than BOX and more than one intermediate layer can be used, in one or more embodiments. Based on the simulations of SAW waves on the RM-LRT-SAW device 100, using LN as the piezoelectric layer 140 on the dielectric layer 130 on the substrate 120, their performance may be characterized as a function of crystal orientations to identify “pure Shear mode” and “pure Rayleigh mode” solutions. It is found that when rotating the crystal orientation, or the “cut” (the Euler angle beta), there are orientations that exist for which the Shear mode is well-excited, but the Rayleigh mode is well suppressed, and there are other orientations where the Shear mode coupling is close to zero, but the Rayleigh mode coupling is in a good range. It is found that the crystal cuts close to LN 120 YX (beta = + 30°) show good coupling for the Rayleigh mode and good suppression of the shear mode. For example, crystal cut angles between 115 degrees and 125 degrees YX, e.g., between Y+115 and Y+125 degrees, offer a good Rayleigh mode coupling and a highly suppressed Shear mode, in accordance with one or more embodiments. In other words, the piezoelectric layer 140 that includes lithium niobate having a crystal cut angles between 115 degrees and 125 degrees YX offers a good Rayleigh mode coupling and a highly suppressed Shear mode. the piezoelectric layer 140 that includes lithium niobate having a crystal cut angles between 110 degrees and 130 degrees YX offers a good Rayleigh mode coupling and a highly suppressed Shear mode. In one or more embodiments, the piezoelectric layer that includes lithium niobate having a crystal cut angle of 120 degrees YX offers a good Rayleigh mode coupling and a highly suppressed Shear mode.

In one or more embodiments, the coupling values, as well as the exact crystal orientation with best spurious mode suppression depend on several factors, including piezo thickness, oxide thickness, IDT metal stack as well as the duty factor. In one or more embodiments, any degrees of freedom can be utilized for optimization of the IDTs 100 (which can be referred to herein as the “IDT stack”), depending on the application. In one or more embodiments, the typical coupling values are in the range of 5 -10%, depending on the specific characteristics of the material compositions and dimension, the IDTs 110 and the resonator geometry.

For many SAW technologies, including temperature compensated SAW (TCSAW) technologies, a major challenge is that the velocities of Rayleigh mode and Shear mode are close to each other. This results in spurious modes falling in the passband or close to the passband for a given resonator. This leads to the requirement for sophisticated schemes for suppressing these modes, as much as possible. As such, a full suppression is typically not achieved. This can be an issue for small signal performance (passband ripples), as well as large signal performance. For standard LRT, the Rayleigh mode is typically below the main shear mode, while its distance varies depending on the chosen LRT stack. For TCSAW, the spurious modes are shear modes. In such devices, the “main shear mode” and its transverse modes reside close to the resonance-to-antiresonance (fs-fp) region of the main mode, which is a disadvantage.

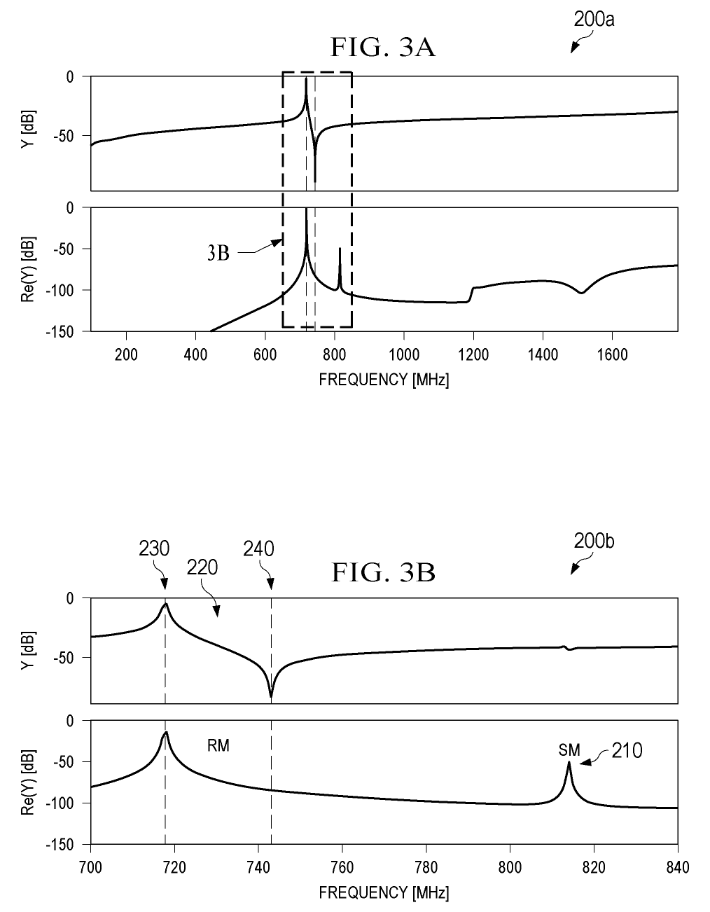

FIGS. 3A and 3B depict graphical representations of a resonator response for an example RM-LRT-SAW device in plots 200a and 200b, according to aspects of the present disclosure. Plot 200b of FIG. 3B shows a near band response, which is a subsection of plot 200a, which is a broad band response, shown in FIG. 3A. As depicted in plots 200a and 200b of FIGS. 3A and 3B, respectively, the out-of-band-response of the example RM-LRT-SAW appear to be very clean. For example, the spurious mode, i.e., the Shear mode 210, shown in FIGS. 3A and 3B, is well outside the resonance-to-anti-resonance (fs-fp) region of the main mode, which is the Rayleigh mode 220, that is identified by the resonant peak 230 (fs 230) and the anti-resonant peak 240 (fp 240).

In contrast, other Rayleigh mode SAW technology, such as TCSAW, suffers from spurious modes (so called plate modes) which exist in the near-band response above fp 240 which may be a problem for multiplexing of filters. To solve this problem with multiplexing of filters, the example RM-LRT-SAW device can be configured to operate at a specific frequency, such as 720 MHz, with highly suppressed spurious modes in a large frequency range (such as from 0 MHz to 1800 MHz, in accordance with one or more embodiments.

In some embodiments, the performance of the RM-LRT-SAW device can be adjusted if the values and properties of the piezoelectric layer or the thickness of the dielectric layer are changed. For example, resonator properties, such as, coupling, capacitance per area, resonant Qs, anti-resonant Qp, can change when the values and properties of the piezoelectric layer or the thickness of the dielectric layer are changed. With such adjustments, coupling values between 5.5% and 9% can be achieved, in some embodiments. In some embodiments, coupling values above 10% can be achieved using the disclosed RM-LRT-SAW technology. In some embodiments, RM-LR-SAW stacks can have coupling values which match well with what is needed to achieve the fractional bandwidths of a typical filter in the 500 MHz - 1.5 GHz frequency range. In some embodiments, capacitance per area values in the range of 100 – 120 pF/mm² indicate that resonator and filter sizes/dimensions using the disclosed RM-LRT-SAW technology can be comparable to, or smaller than, the devices based on the standard LRT.

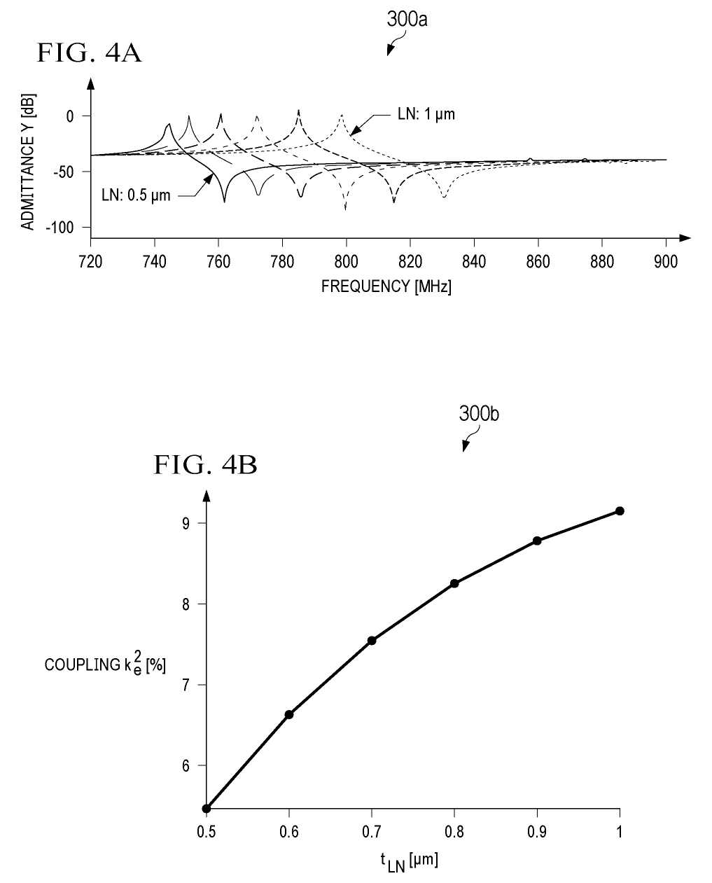

FIGS. 4A and 4B depict graphical representations of how a resonator response changes with changes in the thickness of the piezoelectric layer of an example RM-LRT-SAW device in plots 300a and 300b, according to aspects of the present disclosure. Plot 300a shows how resonator admittance changes as a function of the thickness of the piezoelectric layer, such as lithium niobate (LN). Plot 300b shows how the coupling changes as a function of the thickness of the piezoelectric layer, such as lithium niobate (LN). When the thickness of the piezoelectric layer, i.e., the LN thicknesses, changes between 0.5 µm and 1.0 µm, within the frequency range between 700 MHz and 900 MHz, the admittance peaks shifts from a lower frequency of about 745 MHz at 0.5 µm to a higher frequency of about 795 MHz at 1.0 µm, as shown in FIGS. 4A and 4B. Typical piezoelectric layer thicknesses translate into relative thicknesses in the range of 10% to 30% of the wavelength, lambda, which represents a wavelength of motion, excitation, or acoustic energy of a wave corresponding to the acoustic wave resonator constructed using the disclosed RM-LRT-SAW technology. The coupling can be adjusted by reducing or increasing the LN thickness, in order to match the requirements of specific target bands, such as filter fractional bandwidth, as well as the transition steepness at the lower and upper side of the filter.

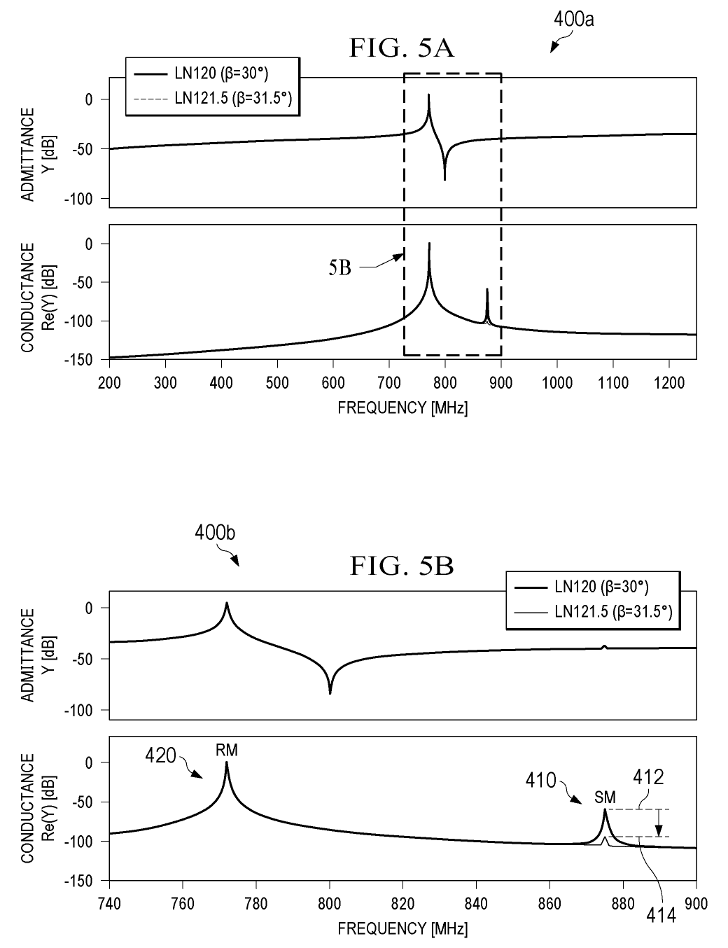

FIGS. 5A and 5B depict graphical representations of a resonator response for an example RM-LRT-SAW device in plots 400a and 400b, according to aspects of the present disclosure. Plot 400b of FIG. 5B shows a near band response, which is a subsection of plot 400a, which is a broad band response, shown in FIG. 5A. As depicted in plots 400a and 400b of FIGS. 5A and 5B, respectively, the out-of-band-response of the example RM-LRT-SAW appear to be very clean. For example, the spurious mode, i.e., the Shear mode 410, shown in FIGS. 5A and 5B, is well outside the resonance-to-anti-resonance (fs-fp) region of the main mode, which is the Rayleigh mode 420. This implies that such spurious resonances will be outside of a filter which employ the RM-LRT-SAW resonators.

Even though the Shear mode 410 can be far above the passband, it is additionally beneficial to fine tune the cut to even better suppress the Shear mode spurious. Having the spurious mode far away and a very good suppression level is the ideal state, that is often hard to achieve for SAW technology. As shown in FIGS. 5A and 5B, for a specific stack, the optimal cut be shifted from 120° YX LN to 121.5° YX LN (i.e., changing the cut angle from 120 degrees to 121.5 degrees), which leads to further improvement in the reduced amplitude of the Shear mode 410 from a high conductance 412 to a low conductance 414, as shown in plot 400b of FIG. 5B.

In one or more embodiments, the performance, e.g., the coupling and capacitance per area, of the disclosed RM-LRT-SAW device can be fine-tuned by changing the pitch and duty factor DF. In one or more embodiments, the capacitance per area increases with the increasing duty factor. In one or more embodiments, the values range from 105 pF/mm² (DF 50%) up to 160 pF/mm² (DF70%) for a RM-LRT-SAW device with a pitch range suitable for typical low-band applications. While for regular LRT, the largest coupling is typically reached at a smaller duty factor around 45% and coupling then reduces when increasing DF further, the largest coupling of 10% can be reached at a duty factor of 65% for the disclosed RM-LRT-SAW device. It is beneficial to reach the maximum coupling at a larger duty factor as can be achieved with the disclosed RM-LRT-SAW device. In some embodiments, the responses of resonators with DF 65% and different pitches can offer a very clean response, coupling values are in the range of 8 - 10%, while capacitance/area is in the range of 95 – 190 pF/mm². Compared to current LRT filters for low band applications, the disclosed RM-LRT-SAW enables a substantial resonator size shrink.

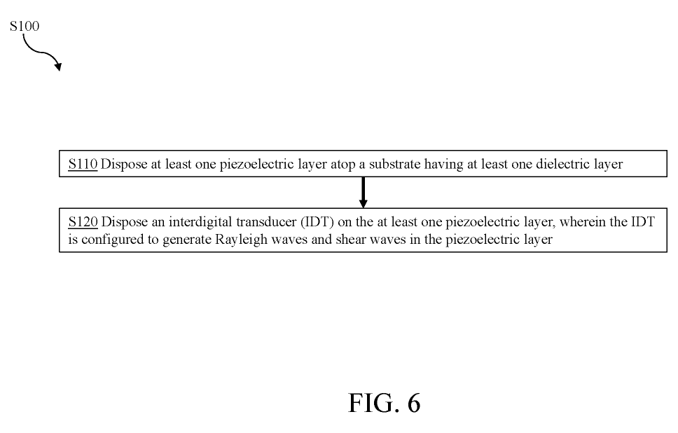

FIG. 6 illustrates a flowchart for a method S100 for preparing a surface acoustic wave device, according to aspects of the present disclosure. In one or more embodiments, the surface acoustic wave device prepared using the method S100 may include a Rayleigh mode low-loss resonator technology surface acoustic wave device, such as the RM-LRT-SAW device 100, as described with respect to FIGS. 1, 2A, 2B, and 2C, with device characteristics/performances as shown and described with respect to FIGS. 3A, 3B, 4A, 4B, 5A, and 5B. In one or more embodiments, a wireless device may include a surface acoustic wave device, such as the RM-LRT-SAW device 100, produced using the method S100 described herein.

As shown in FIG. 6, the method S100 for preparing the surface acoustic wave device includes, at step S110, disposing at least one piezoelectric layer atop a substrate having at least one dielectric layer. In one or more embodiments, the piezoelectric layer may be a piezoelectric layer, such as the piezoelectric layer 14 or 140, the dielectric layer may be a dielectric layer, such as the dielectric layer 130, and the substrate may be a substrate, such as the substrate 12 or 120, as described in FIGS. 1, 2A, 2B, and 2C.

The method S100 further includes, at step S120, disposing an interdigital transducer (IDT) on the at least one piezoelectric layer, wherein the IDT is configured to generate Rayleigh waves and shear waves in the piezoelectric layer. In one or more embodiments, the IDT may be an IDT, such as the IDT 16 or 110, as described in FIGS. 1, 2A, 2B, and 2C.

In one or more embodiments of the method S100, the at least one piezoelectric layer includes a lithium niobate having a crystal cut angle between 115 degrees and 125 degrees YX. In one or more embodiments, the at least one piezoelectric layer includes lithium niobate having a crystal cut angle of 120 degrees YX. In one or more embodiments, the at least one piezoelectric layer has a thickness between about 0.1 µm and about 10 µm. In one or more embodiments, the at least one piezoelectric layer has a thickness between about 0.3 µm and about 1.5 µm.

In one or more embodiments of the method S100, the at least one piezoelectric layer includes lithium tantalate, lithium niobate, or a combination thereof. In one or more embodiments, the at least one dielectric layer includes silicon oxide, aluminum oxide, silicon nitride, silicon oxynitride, or any suitable dielectric material. In one or more embodiments, the at least one dielectric layer includes silicon oxide and has a thickness between about 0.1 µm and about 5 µm. In one or more embodiments, the at least one dielectric layer includes silicon oxide and has a thickness between about 0.5 µm and about 3 µm. In one or more embodiments, the substrate includes silicon, sapphire, quartz, silicon carbide, diamond, or a combination thereof.

In one or more embodiments of the method S100, the shear waves vibrate at a frequency that is about 50 MHz to about 600 MHz larger than an anti-resonant frequency of the generated Rayleigh waves. In one or more embodiments, a difference between an anti-resonant frequency of the generated Rayleigh waves and a resonant frequency of the shear waves is larger than a frequency difference between a resonant frequency and an anti-resonant frequency of the generated Rayleigh waves. In one or more embodiments, the surface acoustic wave device is configured to operate in a Rayleigh mode as a main mode with a shear mode as a spurious mode that is suppressed, wherein the spurious mode has a higher frequency than the main mode. In one or more embodiments, the surface acoustic wave device is configured to operate in a frequency range between about 500 MHz and about 1.5 GHz.

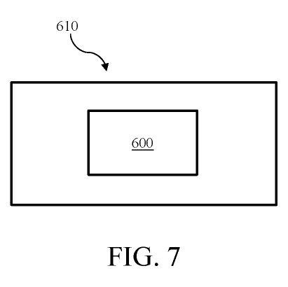

FIG. 7 illustrates an electronic device or a wireless device 610 comprising a surface acoustic wave device 600, according to aspects of the present disclosure. In some implementations, the electronic device or wireless device 610 may include, for example, but not limited to, a computer, a cellular device, a satellite communication device, a wi-fi device, a radar, a global position system device, or any wireless device. In some implementations, the surface acoustic wave device 600 includes a Rayleigh mode low-loss resonator technology surface acoustic wave device, such as the RM-LRT-SAW device 100, as described with respect to FIGS. 1, 2A, 2B, and 2C, with device characteristics/performances as shown and described with respect to FIGS. 3A, 3B, 4A, 4B, 5A, and 5B. The surface acoustic wave device 600 may implement any RF component used in wireless applications, as an example, such as one or more RF filters in a communications system; and the surface acoustic wave device 600 may be coupled to other circuitry for implementing a wireless application.

In one or more embodiments, the surface acoustic wave device 600 of the wireless device 610 includes at least one dielectric layer disposed on a substrate; at least one piezoelectric layer disposed on the at least one dielectric layer; and an interdigital transducer (IDT) disposed on the at least one piezoelectric layer, wherein the IDT is configured to generate Rayleigh waves and shear waves in the piezoelectric layer.

In one or more embodiments of the surface acoustic wave device 600 of the wireless device 610, the piezoelectric layer may be a piezoelectric layer, such as the piezoelectric layer 14 or 140, the dielectric layer may be a dielectric layer, such as the dielectric layer 130, and the substrate may be a substrate, such as the substrate 12 or 120, and the IDT may be an IDT, such as the IDT 16 or 110, as described in FIGS. 1, 2A, 2B, and 2C.

In one or more embodiments of the surface acoustic wave device 600 of the wireless device 610, the at least one piezoelectric layer includes a lithium niobate having a crystal cut angle between 110 degrees and 130 degrees YX. In one or more embodiments, the at least one piezoelectric layer includes a lithium niobate having a crystal cut angle between 115 degrees and 125 degrees YX. In one or more embodiments, the at least one piezoelectric layer includes lithium niobate having a crystal cut angle of 120 degrees YX. In one or more embodiments, the at least one piezoelectric layer has a thickness between about 0.1 µm and about 10 µm. In one or more embodiments, the at least one piezoelectric layer has a thickness between about 0.3 µm and about 1.5 µm.

In one or more embodiments of the surface acoustic wave device 600 of the wireless device 610, the at least one piezoelectric layer includes lithium tantalate, lithium niobate, or a combination thereof. In one or more embodiments, the at least one dielectric layer includes silicon oxide, aluminum oxide, silicon nitride, silicon oxynitride, or any suitable dielectric material. In one or more embodiments, the at least one dielectric layer includes silicon oxide and has a thickness between about 0.1 µm and about 5 µm. In one or more embodiments, the at least one dielectric layer includes silicon oxide and has a thickness between about 0.5 µm and about 3 µm. In one or more embodiments, the substrate includes silicon, sapphire, quartz, silicon carbide, diamond, or a combination thereof.

In one or more embodiments of the surface acoustic wave device 600 of the wireless device 610, the shear waves vibrate at a frequency that is about 50 MHz to about 600 MHz larger than an anti-resonant frequency of the generated Rayleigh waves. In one or more embodiments, a difference between an anti-resonant frequency of the generated Rayleigh waves and a resonant frequency of the shear waves is larger than a frequency difference between a resonant frequency and an anti-resonant frequency of the generated Rayleigh waves.

In one or more embodiments, the surface acoustic wave device is configured to operate in a Rayleigh mode as a main mode with a shear mode as a spurious mode that is suppressed, wherein the spurious mode has a higher frequency than the main mode. In one or more embodiments, the surface acoustic wave device is configured to operate in a frequency range between about 500 MHz and about 1.5 GHz or between about 1.5 GHz and about 3.0 GHz.

Persons skilled in the art will recognize that the apparatus, systems, and methods described above can be modified in various ways. Accordingly, persons of ordinary skill in the art will appreciate that the embodiments encompassed by the present disclosure are not limited to the particular exemplary embodiments described above. In that regard, although illustrative embodiments have been shown and described, a wide range of modification, change, and substitution is contemplated in the foregoing disclosure. It is understood that such variations may be made to the foregoing without departing from the scope of the present disclosure. Accordingly, it is appropriate that the appended claims be construed broadly and in a manner consistent with the present disclosure.

1. A surface acoustic wave (SAW) resonator, comprising:
at least one dielectric layer disposed on a substrate;
at least one piezoelectric layer disposed on the at least one dielectric layer; and
an interdigital transducer (IDT) disposed on the at least one piezoelectric layer, wherein the IDT is configured to generate Rayleigh waves and shear waves in the piezoelectric layer.

2. The surface acoustic wave resonator of claim 1, wherein the at least one piezoelectric layer comprises a lithium niobate having a crystal cut angle between 110 degrees and 130 degrees YX.

3. The surface acoustic wave resonator of claim 1, wherein the at least one piezoelectric layer comprises lithium niobate having a crystal cut angle of 120 degrees YX.

4. The surface acoustic wave resonator of claim 1, wherein the at least one piezoelectric layer has a thickness between about 0.1 µm and about 10 µm.

5. The surface acoustic wave resonator of claim 1, wherein:
the at least one piezoelectric layer comprises lithium tantalate, lithium niobate, or a combination thereof;
the at least one dielectric layer comprises silicon oxide, aluminum oxide, silicon nitride, silicon oxynitride, or any suitable dielectric material;
the substrate comprises silicon, sapphire, quartz, silicon carbide, diamond, or a combination thereof; or
a combination thereof.

6. The surface acoustic wave resonator of claim 1, wherein the shear waves vibrate at a frequency that is about 50 MHz to about 600 MHz larger than an anti-resonant frequency of the generated Rayleigh waves.

7. The surface acoustic wave resonator of claim 1, wherein a difference between an anti-resonant frequency of the generated Rayleigh waves and a resonant frequency of the shear waves is larger than a frequency difference between a resonant frequency and an anti-resonant frequency of the generated Rayleigh waves.

8. The surface acoustic wave resonator of claim 1 is configured to:
operate in a Rayleigh mode as a main mode with a shear mode as a spurious mode that is suppressed, wherein the spurious mode has a higher frequency than the main mode;
operate in a frequency range between about 500 MHz and about 1.5 GHz; or
a combination thereof.

9. A filter comprising:
at least one surface acoustic wave resonator, comprising:
at least one dielectric layer disposed on a substrate;
at least one piezoelectric layer disposed on the at least one dielectric layer; and
an interdigital transducer (IDT) disposed on the at least one piezoelectric layer, wherein the IDT is configured to generate Rayleigh waves and shear waves in the piezoelectric layer.

10. The filter of claim 9, wherein the at least one piezoelectric layer comprises lithium niobate having a crystal cut angle between 115 degrees and 125 degrees YX.

11. The filter of claim 9, wherein the at least one piezoelectric layer comprises lithium niobate having a crystal cut angle of 120 degrees YX.

12. The filter of claim 9, wherein the at least one piezoelectric layer has a thickness between about 0.1 µm and about 10 µm.

13. The filter of claim 9, wherein:
the at least one piezoelectric layer comprises lithium tantalate, lithium niobate, or a combination thereof;
the at least one dielectric layer comprises silicon oxide, aluminum oxide, silicon nitride, silicon oxynitride, or any suitable dielectric material;
the substrate comprises silicon, sapphire, quartz, silicon carbide, diamond, or a combination thereof; or
a combination thereof.

14. The filter of claim 9, wherein the shear waves vibrate at a frequency that is about 50 MHz to about 600 MHz larger than an anti-resonant frequency of the generated Rayleigh waves.

15. The filter of claim 9, wherein a difference between an anti-resonant frequency of the generated Rayleigh waves and a resonant frequency of the shear waves is larger than a frequency difference between a resonant frequency and an anti-resonant frequency of the generated Rayleigh waves.

16. The filter of claim 9, wherein the at least one surface acoustic wave resonator is configured to:
operate in a Rayleigh mode as a main mode with a shear mode as a spurious mode that is suppressed, wherein the spurious mode has a higher frequency than the main mode;
operate in a frequency range between about 500 MHz and about 1.5 GHz; or
a combination thereof.

17. A method for preparing a surface acoustic wave device, comprising:
disposing at least one piezoelectric layer atop a substrate having at least one dielectric layer; and
disposing an interdigital transducer (IDT) on the at least one piezoelectric layer, wherein the IDT is configured to generate Rayleigh waves and shear waves in the piezoelectric layer.

18. The method of claim 17, wherein the at least one piezoelectric layer comprises lithium niobate having a crystal cut angle between 115 degrees and 125 degrees YX, has a thickness between about 0.1 µm and about 10 µm, or a combination thereof.

19. The method of claim 17, wherein:
the at least one piezoelectric layer comprises lithium tantalate, lithium niobate, or a combination thereof;
the at least one dielectric layer comprises silicon oxide, aluminum oxide, silicon nitride, silicon oxynitride, or any suitable dielectric material;
the substrate comprises silicon, sapphire, quartz, silicon carbide, diamond, or a combination thereof; or
a combination thereof.

20. The method of claim 17, wherein:
the shear waves vibrate at a frequency that is about 50 MHz to about 600 MHz larger than an anti-resonant frequency of the generated Rayleigh waves;
a difference between an anti-resonant frequency of the generated Rayleigh waves and a resonant frequency of the shear waves is larger than a frequency difference between a resonant frequency and an anti-resonant frequency of the generated Rayleigh waves;
the surface acoustic wave device is configured to operate in a Rayleigh mode as a main mode with a shear mode as a spurious mode that is suppressed, wherein the spurious mode has a higher frequency than the main mode;
the surface acoustic wave device is configured to operate in a frequency range between about 500 MHz and about 1.5 GHz; or
a combination thereof.
